(19) United States
(12) Patent Application Publication
(10) Pub. No.: US 2004/0134776 A1
(43) Pub. Date: Jul. 15, 2004

(54) Assemblies comprising molybdenum and aluminum; and methods of utilizing interlayers in forming target/backing plate assemblies

(76) Inventors: Josh W. Misner, Spokane, WA (US); Diana Morales, Veradale, WA (US); Jeff A. Keller, Spokane, WA (US)

Correspondence Address: WELLS ST. JOHN P.S., 601 W. FIRST AVENUE, SUITE 1300, SPOKANE, WA, 99201, US

(21) Appl. No.: 10/475,080

(22) PCT Filed: Mar. 29, 2002
(86) PCT No.: PCT/US02/09640

(30) Foreign Application Priority Data
Apr. 26, 2001 (US) 60287233

(51) Int. Cl. C23C 14/34; B23K 28/00

(52) U.S. Cl. 204/298.12; 204/298.13; 228/194

(57) ABSTRACT

The invention includes an assembly (130) having a physical vapor deposition target (102) separated from a backing plate (120) with a layer (104) consisting essentially of one or both of molybdenum and tantalum. The invention also includes an assembly comprising a backing plate of at least 99.9% aluminum bound to a target of at least 99.9% molybdenum through a bond having a strength of at least about 6,000 pounds per square inch (psi). Additionally, the invention includes a method of bonding a tungsten-containing material to an aluminum-containing material. A layer of molybdenum-containing material (104) is provided between the tungsten-containing material (102) and the aluminum-containing material (120); and is bonded to both the tungsten-containing material (102) and the aluminum-containing material (120).

### TECHNICAL FIELD

The invention pertains to various assemblies, including physical vapor deposition (PVD) target/backing plate assemblies. In particular aspects, the invention pertains to assemblies comprising molybdenum bonded to aluminum. The invention can also pertain to methods of bonding physical vapor deposition targets to backing plates utilizing an interlayer comprising one or both of molybdenum and tantalum.

### BACKGROUND OF THE INVENTION

Physical vapor deposition is frequently utilized for forming a layer of material over a substrate. In a physical vapor deposition process, a surface of a target is exposed to high energy ions and/or other particles, which causes material from the target surface to be dislodged. The dislodged material can travel to a substrate proximate the target and deposit across the substrate as a thin film.

Targets can be formed of any of a number of materials which are desired to be deposited across a substrate. For instance, targets can be formed of various metals, including, for example, tungsten, molybdenum, copper, aluminum, tantalum, etc.

Targets are frequently bonded or otherwise attached to a backing plate prior to being utilized for physical vapor deposition. A backing plate is utilized to physically retain a target in a physical vapor deposition apparatus, and will typically have a particular geometry suitable for being retained in the apparatus. Backing plates can be formed of numerous materials, with an exemplary material being aluminum.

Difficulties can occur in attempting to bond targets with suitable backing plates. One method of bonding a target material to a backing plate is to form an indium solder bond between the backing plate and the target material. For instance, a refractory metal target material (such as tungsten or molybdenum) can be solder-bonded to a copper backing plate. However, the solder bond will melt if too much power is applied to the target/backing plate assembly (due to heating associated with the flow of power through the assembly), and accordingly assemblies comprising indium solder bonds are typically operated at less than 4 kilowatts of power.

Unfortunately, 4 kilowatts of power is often less than an amount of power desired for effective sputtering. It can be advantageous to utilize 10 kilowatts or more of power, since operating at a higher power can improve productivity and allow for more output from a single sputtering target. It is therefore desirable to develop target/backing plate constructions which can tolerate relatively high power during sputtering operations.

One method of forming a target/backing plate construction capable of tolerating relatively high power is to directly bond the backing plate to the target, rather than utilizing a solder layer between the target and backing plate. However, if the target and backing plate have substantially different thermal expansion characteristics relative to one another, cracks and/or breakage can occur along the diffusion bond during operation of the target/backing plate construction. Such problem occurs, for example, in applications in which tungsten is bonded to aluminum or copper.

It would be desirable to develop new target/backing plate constructions which are suitable for operation at a power of 10 kilowatts or higher.

It is to be understood that although the invention was motivated by the above-discussed problems and considerations, the invention described below is not limited to target/backing plate constructions, except to the extent that target/backing plate constructions are explicitly recited in the claims which follow.

### SUMMARY OF THE INVENTION

In one aspect, the invention encompasses a physical vapor deposition target/backing plate assembly. The assembly includes a physical vapor deposition target, a backing plate, and a layer between the backing plate and target. The layer comprises one or both of molybdenum and tantalum.

In one aspect, the invention encompasses an assembly comprising a backing plate of at least 99.9% aluminum bound to a target of at least 99.9% molybdenum through a bond having a strength of at least about 6,000 pounds per square inch (psi).

In one aspect, the invention encompasses a method of bonding a tungsten-containing material to an aluminum-containing material. A layer of molybdenum-containing material is provided between the tungsten-containing material and the aluminum-containing material. The molybdenum-containing material is bonded to both the tungsten-containing material and the aluminum-containing material.

### BRIEF DESCRIPTION OF THE DRAWINGS

Preferred embodiments of the invention are described below with reference to the following accompanying drawings.

FIG. 1 is a diagrammatic, cross-sectional view of a physical vapor deposition target at an initial stage of an exemplary aspect of the present invention.

FIG. 2 is a top view of the FIG. 1 target.

FIG. 3 is a top view of the FIG. 1 target, shown at a processing step subsequent to that of FIG. 2.

FIG. 4 is a diagrammatic, cross-sectional view of a backing plate.

FIG. 5 is a top view of the FIG. 4 backing plate.

FIG. 6 is a cross-sectional view of the FIG. 4 backing plate bonded to the target of FIG. 3.

FIG. 7 is a diagrammatic, cross-sectional view of a target/layer assembly.

FIG. 8 is a top view of the FIG. 7 assembly.

FIG. 9 is a top view of the FIG. 7 assembly shown at a processing step subsequent to that of FIG. 7.

FIG. 10 is a view of the FIG. 7 assembly shown at a processing subsequent to that of FIG. 9, and shown bonded with a backing plate.

FIG. 11 is a flow chart diagram of an exemplary aspect of the present invention.

FIG. 12 is a flow chart diagram of another exemplary aspect of the present invention.

### DETAILED DESCRIPTION OF THE PREFERRED EMBODIMENTS

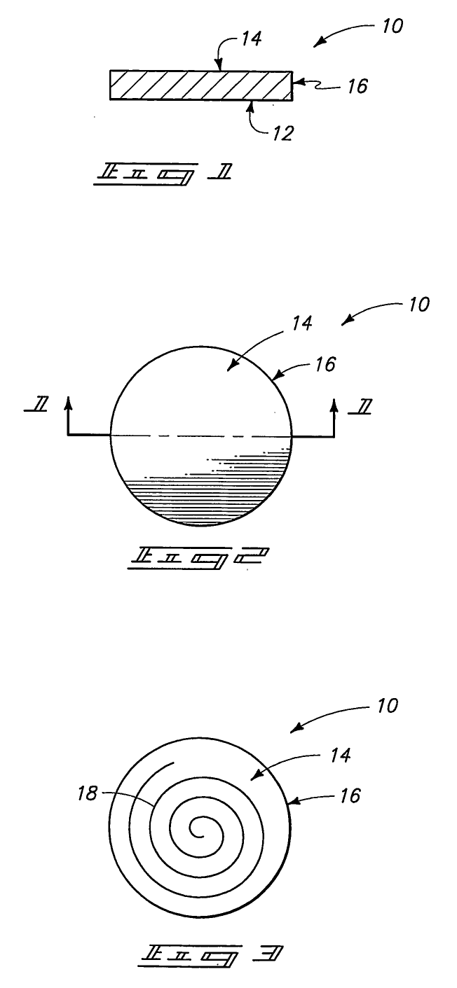

An exemplary embodiment of the invention is described with reference to FIGS. 1-6. Referring first to FIGS. 1 and 2, an exemplary target 10 is illustrated in cross-sectional view in FIG. 1, and top view in FIG. 2. Target 10 comprises a disc shape. More specifically, target 10 has a first surface 12, and an opposing second surface 14. Surfaces 12 and 14 are joined by a circular outer periphery 16. Target 10 is shown in an exemplary shape, and it is to be understood that other target shapes can be utilized in various applications of the present invention.

Target 10 can comprise any of numerous compositions. In particular applications, target 10 can comprise, consist essentially of, or consist of one or more of molybdenum, tantalum, tungsten, titanium, silicon and aluminum. For instance, target 10 can be at least 99.9% pure in aluminum, at least 99.9% pure in tungsten, at least 99.9% pure in a metal silicide (such as, for example, tungsten silicide or titanium silicide), or at least 99.9% pure in an aluminide (such as, for example, tungsten aluminide). The purity of the target material is described herein in terms of weight purity, and accordingly a material described as being 99.9% pure can be considered to have up to 1 part per thousand (by weight) of impurity.

In particular applications, the target can consist essentially of two or more metals, with an exemplary composition consisting essentially of tungsten and titanium. In further exemplary applications, the target can comprise, consist essentially of, or consist of a material having a coefficient of thermal expansion less than 8, with exemplary materials being tungsten in combination with one or both of aluminum and silicon.

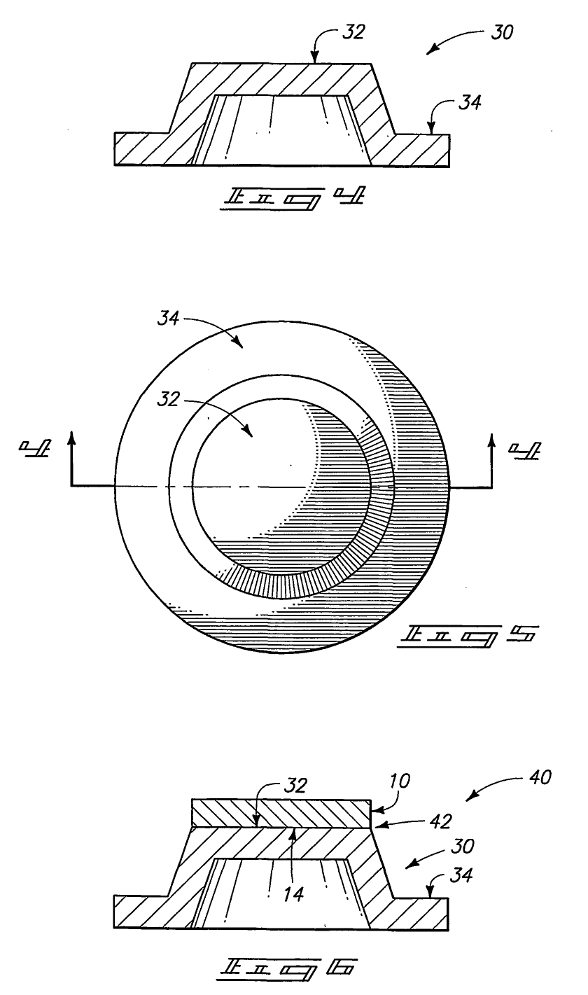

Referring to FIG. 3, a pattern 18 is scrolled into surface 14 of target 10. Pattern 18 can be formed utilizing a computer numerically controlled (CNC) lathe. Pattern 18 is an exemplary pattern, and any suitable pattern can be used. Ultimately, a material will be pressed against surface 14 of target 10 and diffusion bonded to the surface. Scroll pattern 18 can enhance the strength of the bond. For instance, if the material pressed against surface 14 is softer than the composition of target 10, some of the material can be pressed into scroll pattern 18 during a diffusion bonding process.

In one aspect of the invention, target 10 is diffusion bonded directly to a backing plate. In such aspect, target 10 can comprise molybdenum, and the backing plate can comprise aluminum, such as, for example, 6061 series aluminum.

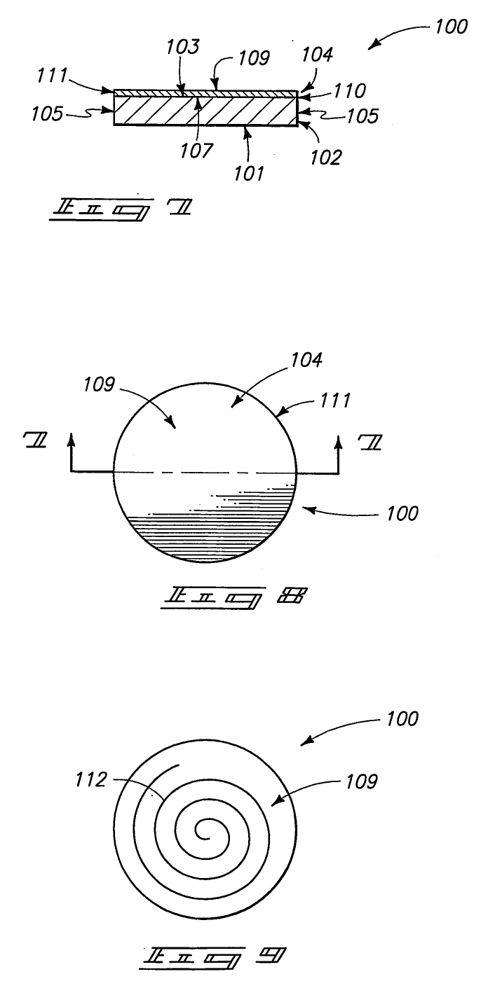

A configuration of a backing plate is illustrated in FIGS. 4 and 5 as a backing plate 30. Such configuration corresponds to an ENDURA™ configuration, as is available from Honeywell International Inc. The configuration of FIGS. 4 and 5 is an exemplary configuration, and other configurations can be utilized in various aspects of the present invention.

Backing plate 30 comprises an upper surface 32, which is ultimately bonded to a target. Backing plate 30 also comprises a flange 34 extending around a periphery of the backing plate, and suitable for utilization in retaining the backing plate within a physical vapor deposition apparatus.

Referring to FIG. 6, target 10 is shown bonded to backing plate 30 to form a target/backing plate assembly 40. More specifically, surface 14 of target 10 has been bonded to surface 32 of backing plate 30 to form a diffusion bond 42 at an interface between target 10 and backing plate 30.

The diffusion bond can be formed as follows. Initially, target 10 is provided with the scrolled pattern 18 as shown in FIG. 3. Subsequently, the surface 14 of target 10 is cleaned with suitable degreasers and/or other solvents to remove contaminants, such as, for example, machining oils, from the surface. Exemplary solvents which can be utilized are acetone and hexane. It is preferred that the cleaning agent does not oxidize a surface of target 10. Accordingly, if the target consists essentially of molybdenum, it can be preferred that the cleaning agent does not include nitric acid. Upper surface 32 of backing plate 30 can also be cleaned with a suitable cleaning agent.

The cleaned surface 14 is placed against cleaned upper surface 32 of backing plate 30. Subsequently, the assembly comprising target 10 and backing plate 30 is subjected to hot pressing under conditions which, for example, provide from about 4,000 psi to about 8,000 psi of pressure across the interface between surfaces 14 and 32, while heating the target/backing plate assembly to a temperature of from about 400° C. to about 1600° C. (typically the temperature is from about 400° C. to about 600° C., such as, for example, about 500° C., when bonding aluminum to molybdenum). The assembly is maintained under the pressure of from about 4,000 psi to about 8,000 psi and the temperature of from 400° C. to about 1600° C. for a time of from about 1 hour to about 5 hours (typically from about 1 hour to about 3 hours), and preferably is under a vacuum of less than or equal to about 3×10⁻⁴ Torr.

The above-described processing can be utilized to, for example, form a strong diffusion bond between molybdenum and aluminum when bonding a molybdenum-containing target 10 to an aluminum-containing backing plate 30. Table 1 describes various diffusion bonds between aluminum and molybdenum which have been achieved utilizing methodology of the present invention. The bond strengths reported in Table 1 were determined by a ram tensile test.

TABLE 1

| Sample No. | Bond Strength (psi) |
|---|---|
| 1 | 8,891 |
| 2 | 7,464 |
| 3 | 8,954 |
| 4 | 8,774 |
| 5 | 9,720 |
| 6 | 8,993 |
| 7 | 9,845 |
| 8 | 8,619 |
| 9 | 9,943 |
| 10 | 10,016 |

As evidenced by Table 1, bonds between aluminum and molybdenum formed in accordance with methodology of the present invention have been determined to have strengths of at least about 6,000 psi, at least about 7,000 psi, at least about 8,000 psi, at least about 9,000 psi, and in particular applications at least about 10,000 psi.

The strong bonds formed in accordance with methodology of the present invention can be suitable for bonding of physical vapor deposition targets to backing plates, as the bonds can be durable during relatively high power sputtering operations. Accordingly, a bond formed between a molybdenum-containing target and an aluminum-containing backing plate in accordance with the methodology described above can form a target/backing plate assembly durable to exposure of 10 kilowatts or more of power during a sputtering operation.

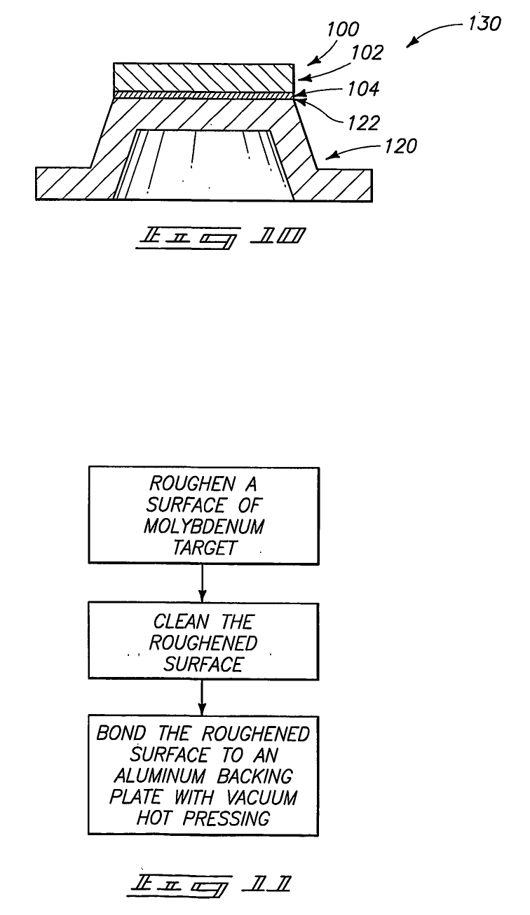

Another aspect of the invention is described with reference to FIGS. 7-10. Referring to FIGS. 7 and 8, an assembly 100 is illustrated comprising a target 102 and a layer 104 over the target. Target 102 comprises a surface 101, an opposing surface 103, and a circular outer periphery 105 joining surfaces 101 and 103. Target 102 can comprise a geometry similar to that described above with reference to the target 10 of FIG. 1. Layer 104 comprises a surface 107 against target 102, and an opposing surface 109. Layer 104 further comprises a circular outer periphery 111 joining surfaces 107 and 109.

Target 102 can comprise materials having a coefficient of thermal expansion less than 8, including various aluminides and suicides. As another example, target 102 can comprise at least 99% tungsten or tungsten compounds, such as, for example, tungsten aluminide, tungsten suicide, and/or alloys of tungsten and other metals (for instance, alloys of tungsten and titanium).

An interface 110 is defined where surface 107 of layer 104 joins surface 103 of target 105. In particular aspects of the present invention, a diffusion bond is formed along such interface. For instance, target 102 can consist essentially of a material having a coefficient of thermal expansion less than 8, and layer 104 can comprise, consist essentially of, or consist of one or both of molybdenum and tantalum. It is recognized that molybdenum and tantalum have coefficients of thermal expansion comparable to materials having coefficients of thermal expansion less than 8. Accordingly, a diffusion bond formed between a layer 104 comprising molybdenum and/or tantalum, and a target 102 comprising a material having a coefficient of thermal expansion less than 8 will be relatively robust. In other words, such diffusion bond will withstand cracking or breaking at relatively high temperatures and/or power levels passed through an assembly comprising the diffusion bond, as the coefficient of thermal expansion of layer 104 will be comparable to the coefficient of thermal expansion of target 102.

Targets suitable for utilization with layers comprising one or both of tantalum and molybdenum include targets which comprise tungsten, either alone, or in combination with one or more of silicon, aluminum and titanium. For instance, the targets can comprise, consist essentially of, or consist of tungsten silicide, tungsten aluminide, or combinations of tungsten and titanium. In a particular aspect of the present invention, target 102 is formed of tungsten having a purity of at least 99.9%, and layer 104 consists essentially of either molybdenum or tantalum.

During the processing utilized to form the assembly 100 of FIG. 7, an exemplary molybdenum material of layer 104 can diffuse from about 0.3 microns to about 0.5 microns deep into an exemplary tungsten target. Further, if a scroll pattern has been formed in the tungsten target, the diffusing material can fill the scroll pattern. Accordingly, a chemical and mechanical bond can be formed between the layer 104 and the target 102.

A pattern comparable to that described in FIG. 3 can be scrolled into either surface 103 of target 102 or surface 107 of layer 104 prior to forming the assembly 100. Further, surfaces 107 and 103 can be cleaned with suitable solvents and/or degreasers prior to forming the assembly 100. Subsequently, assembly 100 is subjected to suitable processing to form a diffusion bond between layer 104 and target 102. Such processing can be identical to that described above with reference to FIG. 6 for forming a diffusion bond between a target and backing plate. Accordingly, the processing can include subjecting assembly 100 to a pressure of from about 4,000 psi to about 8,000 psi, for a time of from about 1 hour to about 5 hours, while maintaining the assembly at a temperature of from about 400° C. to about 1600° C. (typically the temperature is from about 1200° C. to about 1600° C. when bonding tungsten to one or both of molybdenum and tantalum), and while keeping the assembly under a vacuum of less than or equal to about 3×10⁻⁴ Torr.

Referring to FIG. 9, a pattern 112 is scrolled into surface 109 of assembly 100. Pattern 112 can be formed by, for example, a CNC lathe. Pattern 112 is an exemplary pattern, and other patterns can be formed in various aspects of the present invention. After pattern 112 is formed, surface 109 is cleaned with, for example, a suitable solvent and/or degreaser to remove machine oils from the surface.

The scroll pattern shown in FIG. 9 is but one exemplary method of preparing surface 109 for subsequent diffusion bonding. Alternatively, and/or additionally, surface 109 can be treated by bead or grit blasting. If bead or grit blasting is utilized, surface 109 will preferably be roughened to a thickness of at least about 250 microinches. The roughening of surface 109 provides a plurality of ridges that can penetrate through aluminum oxide that may be present on the backing plate 120 to allow good contact between the material of surface 109 (which can be, for example, elemental molybdenum and/or elemental tantalum), and the material of backing plate 120 (which can be, for example, elemental aluminum) during subsequent diffusion bonding of layer 104 to backing plate 120. Bead and/or grit blasting can also be utilized in the aspect of the invention described above with reference to FIG. 3.

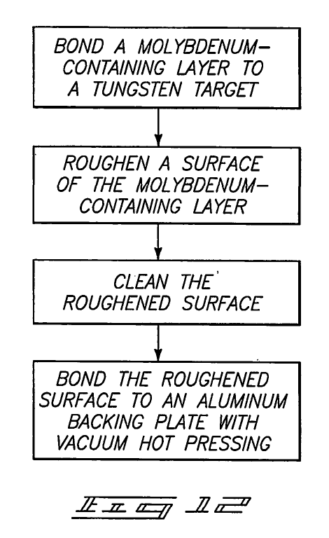

Referring to FIG. 10, assembly 100 is bonded to a backing plate 120 to form a target/backing plate assembly 130. More specifically, surface 109 (FIG. 9) is bonded to an upper surface of the backing plate 120. Such can occur through, for example, a hot pressing process of the type described above with reference to FIG. 6, and forms a diffusion bond at an interface 122 between layer 104 and backing plate 120. Layer 104 can have a thickness of, for example, about 0.15 inches at the processing stage of FIG. 7, and such can be reduced to a thickness of about 0.1 inches after the processing of FIG. 10. Additionally, machining can be utilized after the processing of FIG. 7, and prior to that of FIG. 10, to reduce a thickness of layer 104, if such reduction is desired.

In particular applications, backing plate 120 can comprise, consist essentially of, or consist of aluminum (for instance, backing plate 120 can be 99.9% pure aluminum), layer 104 is 99.9% pure in molybdenum and/or tantalum, and target 102 is 99.9% pure in tungsten. In such applications, interlayer 104 can provide strong bonding between target 102 and backing plate 120 so that the target/backing plate assembly 130 is durable to PVD processes utilizing 10 kilowatts of power or more. A strength of the diffusion bond between layer 104 and an aluminum-comprising material 120 can be comparable to the strength described in Table 1, and further a strength between a molybdenum layer 104 and a tungsten target 102 can be greater than 10,000 psi. It is noted that tantalum and molybdenum have the same crystal structure as tungsten, high melting points, similar coefficients of thermal expansion, and both readily diffuse into tungsten. Accordingly, a diffusion bond between tungsten and tantalum and/or molybdenum can be strong, and durable to changes in temperature. Exemplary strengths of tungsten/molybdenum diffusion bonds are described in Table 2.

TABLE 2

| Sample No. | Bond Strength (psi) |
|---|---|
| 1 | 16,383 |
| 2 | 13,784 |
| 3 | 14,985 |

The layer 104 of assembly 130 can absorb shock of thermal expansion as the assembly is heated in, for example, a physical vapor deposition process. Accordingly, layer 104 can enable assembly 130 to be more durable to heating and cooling than would an assembly comprising target 102 directly bonded to backing plate 120.

Although the processing of FIGS. 7-10 joins layer 104 to target 102 prior to joining layer 104 to backing plate 120, it is noted that the ordering of various stages of the process can be altered. For instance, layer 104 can be provided between target 102 and backing plate 120 in a first stage, and subsequently diffusion bonded to both target 102 and backing plate 120 simultaneously during subsequent hot pressing. Alternatively, layer 104 can be first bonded to backing plate 120 utilizing a hot pressing process to form a diffusion bond between layer 104 and backing plate 120; and subsequently target 102 can be bonded to layer. 104 with a second hot pressing process to form a diffusion bond between the target and layer.

In a particular aspect of the invention, target 102 can be considered a tungsten containing material, backing plate 120 can be considered an aluminum-containing material, and layer 104 can be considered a molybdenum-containing material between and bonded to both the tungsten-containing material and the aluminum-containing material.

Although hot pressing is described as being a preferred method for forming the diffusion bond between layer 104 and target 102, as well as for forming the diffusion bond between layer 104 and backing plate 120, it is to be understood that other methods can be utilized for providing the pressure and temperature suitable for forming such diffusion bonds. For instance, a hot isostatic press can also be utilized for forming various of the diffusion bonds described above.

The shapes 10 and 100 are referred to as targets throughout the discussion above, even though the shapes may be considered by some to be target blanks, rather than targets, at various stages of the processing. Specifically, a material is sometimes considered to be a “target blank”, rather than a “target” at processing up until the material is in a form which can be placed in a physical vapor deposition apparatus and actually utilized as a target. Accordingly, the shapes 10 and 100 could be considered to be target blanks up until the shapes are bonded to backing plates and formed into final configurations suitable for utilization in a physical vapor deposition apparatus. The shapes may be in the desired final configurations immediately after bonding the shapes to backing plates, or it may be desired to do some additional machining to the shapes after bonding the shapes to backing plates. Although there is sometimes a difference specified between targets and target blanks, it is also common for the term “target” to be loosely utilized in current jargon to refer to both targets and target blanks. For purposes of interpreting this disclosure and the claims that follow, the term “target” is to be understood as encompassing both targets and target blanks, unless explicitly stated otherwise.

FIGS. 11 and 12 are flow-chart diagrams illustrating particular methods that can be utilized in various aspects of the present invention. Referring first to FIG. 11, such describes an aspect of bonding a molybdenum target to an aluminum backing plate to form a backing plate/target construction. Specifically, a surface of a molybdenum target is roughened, with such roughening comprising, for example, the methodology described above with reference to FIG. 3. The roughened surface is then cleaned with appropriate solvents and/or degreasing materials. Also, a surface of a backing plate to which the target is ultimately to be bonded can be cleaned with the solvents and/or degreasers.

Subsequently, the roughened surface of the molybdenum target is bonded to the aluminum backing plate utilizing vacuum hot pressing (such as, for example, the vacuum hot pressing described above with reference to FIG. 6) to form a target/backing plate assembly.

The process of FIG. 12 begins with a step in which a molybdenum-containing layer is bonded to a tungsten target. Such can be accomplished utilizing, for example, the methodology described with reference to FIG. 7, wherein vacuum hot pressing is utilized to bond a layer to a target.

Subsequently, a surface of the molybdenum-containing layer is roughened. Such can be accomplished utilizing, for example, the processing described above with reference to FIG. 9.

The roughened surface is cleaned with an appropriate solvent and/or degreasing agent.

Subsequently, the roughened surface is bonded to an aluminum backing plate utilizing vacuum-hot pressing. Such can form an assembly similar to that described with reference to FIG. 10, with the target 102 being a tungsten target, the layer 104 being a molybdenum-containing layer, and the backing plate 120 being an aluminum backing plate.

1. An assembly comprising:
a backing plate comprising at least about 99.9% aluminum;
a target comprising at least about 99.9% molybdenum; and
a bond between the aluminum and molybdenum having a strength of at least about 6000 psi.

2. The assembly of claim 1 wherein the bond between the aluminum and molybdenum has a strength of at least about 7000 psi.

3. The assembly of claim 1 wherein the bond between the aluminum and molybdenum has a strength of at least about 8000 psi.

4. The assembly of claim 1 wherein the bond between the aluminum and molybdenum has a strength of at least about 9000 psi.

5. The assembly of claim 1 wherein the bond between the aluminum and molybdenum has a strength of at least about 10,000 psi.

6. An assembly comprising:
a backing plate comprising at least 99.9% aluminum;
a target comprising at least 99.9% tungsten or tungsten compounds; and
a molybdenum-containing interface material between the target and backing plate; a bond between the aluminum-containing backing plate and the molybdenum-containing interface material having a strength of at least about 6000 psi.

7. The assembly of claim 6 wherein the bond between the aluminum-containing backing plate and the molybdenum-containing interface material has a strength of at least about 7000 psi.

8. The assembly of claim 6 wherein the bond between the aluminum-containing backing plate and the molybdenum-containing interface material has a strength of at least about 8000 psi.

9. The assembly of claim 6 wherein the bond between the aluminum-containing backing plate and the molybdenum-containing interface material has a strength of at least about 9000 psi.

10. The assembly of claim 6 wherein the bond between the aluminum-containing backing plate and the molybdenum-containing interface material has a strength of at least about 10,000 psi.

11. A method of forming an assembly comprising a W-containing material and an Al-containing material comprising:
bonding an Mo-containing material to the W-containing material; and
bonding the Mo-containing material to the Al-containing material; a bond between the Al-containing material and the Mo-containing material having a strength of at least about 6000 psi.

12. The method of claim 11 wherein
the layer of Mo-containing material is provided on the W-containing material and diffusion bonded to the W-containing material to form a first assembly; and
after the first assembly is formed, the Al-containing material is diffusion bonded to the Mo-containing material.

13. The method of claim 11 wherein the Mo-containing material is at least about 99.9% pure in molybdenum.

14. The method of claim 11 wherein the W-containing material is at least about 99.9% pure in tungsten.

15. The method of claim 11 wherein the Al-containing material is at least about 99.9% pure in aluminum.

16. The method of claim 11 wherein the bonding the Mo-containing material to the Al-containing material comprises pressing the Mo-containing material against the Al-containing material under a pressure of at least about 4000 psi and a temperature of at least about 400° C. for a duration of at least about 1 hour.

17. The method of claim 16 further comprising maintaining the Al-containing material and the Mo-containing material under a vacuum of at least about 3×10⁻⁴ Torr during the pressing.

18. The method of claim 16 wherein the pressure is from about 4000 psi to about 8000 psi.

19. The method of claim 16 wherein the temperature is from about 400° C. to about 600° C.

20. The method of claim 16 wherein the duration is less than about 5 hours.

21. The method of claim 16 wherein the duration is from about 1 hour to about 3 hours.
